(19) United States
(12) Patent Application Publication
(10) Pub. No.: US 2026/0327524 A1
(43) Pub. Date: Oct. 22, 2026

(54) DRY ETCHING RESIDUE REMOVING SOLUTION

(71) Applicant: TOKUYAMA CORPORATION, Yamaguchi (JP)

(72) Inventors: Hiroto YARIMIZU, Yamaguchi (JP); Yuki KIKKAWA, Yamaguchi (JP); Tomoaki SATO, Yamaguchi (JP)

(73) Assignee: TOKUYAMA CORPORATION, Yamaguchi (JP)

(21) Appl. No.: 19/113,684

(22) PCT Filed: Sep. 29, 2023
(86) PCT No.: PCT/JP2023/035770

§ 371 Date: Mar. 20, 2025

(30) Foreign Application Priority Data
Sep. 29, 2022 (JP) 2022-155886

(51) Int. Cl. C11D 3/395; H10P 50/26; H10P 70/00

(52) U.S. Cl. CPC C11D 3/3955; H10P 50/267; H10P 70/273

(57) ABSTRACT

Provided is a dry etching residue removing solution containing: at least one oxidizer selected from the group consisting of hypobromite ions, bromate ions, bromite ions, hypochlorite ions, chlorate ions, and chlorite ions; at least one metal selected from the group consisting of Mg, Ca, Na, and K; and water, wherein the pH of the residue removing solution is 9.5-14 at 25° C., and the total content of Mg, Ca, Na, and K in the dry etching residue removing solution is 0.01-1000 ppt.

### TECHNICAL FIELD

The present invention relates to a residue removing solution for removing a residue after dry etching in a production process of a semiconductor device.

### BACKGROUND ART

In a semiconductor device, a wiring layer is formed for the purpose of taking out an electrical signal generated by a transistor to the outside. Semiconductor devices are made finer year by year, and the use of a material with low electromigration resistance or a high resistance value causes a decrease in reliability of the semiconductor device or inhibition of high-speed operation. This leads to a desire for a material with high electromigration resistance and a low resistance value as a wiring material.

Examples of such materials include aluminum and copper, which have been used to date, and tungsten, cobalt, molybdenum, and ruthenium, which have recently been studied. In a case where a wiring layer is formed in a semiconductor device, a step of processing a wiring material is included, and dry or wet etching is used in this step.

In a case where the wiring material is ruthenium, and ruthenium is wet-etched under alkaline conditions, ruthenium dissolves as, for example, RuO₄⁻ or RuO₄²⁻ in a residue removing solution. RuO₄⁻ and RuO₄²⁻ change to RuO₄ in the residue removing solution, and a portion of it is gasified and released into a gas phase. RuO₄ is strongly oxidizing and thus is not only harmful to the human body but also easily reduced to produce RuO₂ particles. In general, particles lead to a decrease in yield, thus causing a serious problem in a semiconductor formation step. From such a background, suppression of the generation of RuO₄ gas is very important.

Patent Document 1 proposes a residue removing solution for a semiconductor wafer, the solution containing a hypochlorite ion, exhibiting an excellent etching rate and stability of the etching rate, and capable of suppressing generation of RuO₄ gas.

Patent Document 2 proposes a residue removing solution for a semiconductor wafer, the solution containing a hypobromite ion, exhibiting an excellent etching rate and stability of the etching rate, and capable of suppressing generation of RuO₄ gas.

### PRIOR ART DOCUMENTS

### Patent Document

Patent Document 1: WO 2019/142788
Patent Document 2: WO 2021/059666

### SUMMARY OF INVENTION

### Technical Problem

In a case where a wiring material is dry-etched, an etching residue which is a by-product generated by the dry-etching may be generated. It is known that impurities such as an etching residue may cause adverse effects such as a decrease in yield and a decrease in reliability of a semiconductor device to be produced. The etching residue is removed by a wet etching solution, but the wet etching solution in the related art has a problem in that the storage stability of an oxidizing agent contained in the wet etching solution is poor.

Accordingly, the present invention is directed to providing an etching residue removing solution having a high effect of removing an etching residue, in which an oxidizing agent has good storage stability.

### Solution to Problem

The present inventors have conducted diligent research to solve the above problems. That is, the present invention is configured as follows.

Aspect 1. A dry etching residue removing solution for removing a residue after dry etching, the dry etching residue removing solution containing:
one or more oxidizing agents selected from the group consisting of a hypobromite ion, a bromite ion, a bromate ion, a hypochlorite ion, a chlorite ion, and a chlorate ion; one or more metals selected from the group consisting of Mg, Ca, Na, and K; and water, wherein
the residue removing solution has a pH of 9.5 or higher and 14 or lower at 25° C., and a total content of Mg, Ca, Na, and K in the dry etching residue removing solution is 0.01 ppt or more and 1000 ppt or less.

Aspect 2. The dry etching residue removing solution according to aspect 1, wherein a concentration of the oxidizing agent is 0.0001 mol/L or more and 0.40 mol/L or less.

Aspect 3. The dry etching residue removing solution according to aspect 1, wherein the oxidizing agent is a hypochlorite ion, and a concentration of the hypochlorite ion is 0.001 mol/L or more and 0.40 mol/L or less.

Aspect 4. The dry etching residue removing solution according to aspect 2, wherein the oxidizing agent is a hypobromite ion, and a concentration of the hypobromite ion is 0.001 mol/L or more and 0.20 mol/L or less.

Aspect 5. The dry etching residue removing solution according to any one of aspects 1 to 4, further containing an onium ion, wherein the residue removing solution has a surface tension of 60 mN/m or more and 75 mN/m or less.

Aspect 6. The dry etching residue removing solution according to aspect 5, wherein the onium ion is one or more selected from the group consisting of onium ions represented by Formula (1) to Formula (6):

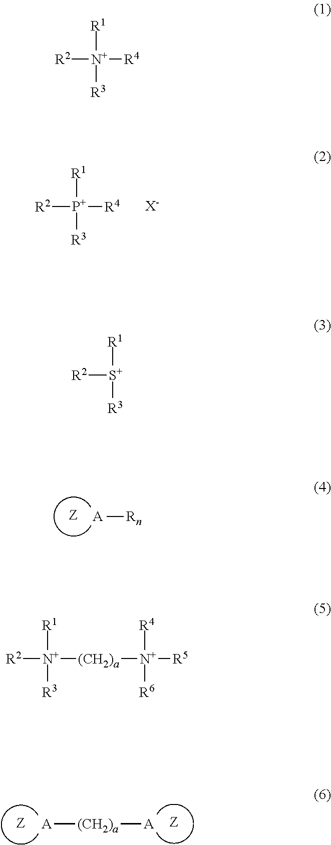

(in Formula (1) to Formula (6),
R¹, R², R³, R⁴, R⁵, and R⁶ are each independently an alkyl group having a carbon number from 2 to 9, an allyl group, an aralkyl group having an alkyl group having a carbon number from 1 to 9, or an aryl group, at least one hydrogen in an aryl group and a ring of an aryl group in the aralkyl group is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9, and at least one hydrogen in these groups is optionally substituted with fluorine, chlorine, bromine, or iodine,
A is an ammonium ion or a phosphonium ion,
Z is an aromatic group or alicyclic group which optionally contains a nitrogen, sulfur, or oxygen atom, and in the aromatic group or the alicyclic group, carbon or nitrogen optionally has chlorine, bromine, fluorine, iodine, at least one alkyl group having a carbon number from 1 to 9, at least one alkenyloxy group having a carbon number from 2 to 9, an aromatic group which is optionally substituted with at least one alkyl group having a carbon number from 1 to 9, or an alicyclic group which is optionally substituted with at least one alkyl group having a carbon number from 1 to 9,
R is chlorine, bromine, fluorine, iodine, an alkyl group having a carbon number from 1 to 9, an allyl group, an aromatic group which is optionally substituted with at least one alkyl group having a carbon number from 1 to 9, or an alicyclic group which is optionally substituted with at least one alkyl group having a carbon number from 1 to 9, n is an integer of 1 or 2 and represents the number of R, when n is 2, Rs are optionally the same or different and optionally form a ring, and
a is an integer of 1 to 10).

Aspect 7. The dry etching residue removing solution according to aspect 5 or 6, wherein a concentration of the onium ion is 1 mass ppm or more and 10000 mass ppm or less.

Aspect 8. A method for removing a dry etching residue of a semiconductor wafer, the method including a step of bringing the dry etching residue removing solution according to any one of aspects 1 to 7 into contact with a semiconductor wafer.

Aspect 9. A method for producing a semiconductor device, the method including a step of dry-etching a semiconductor wafer; and a step of removing a dry etching residue with the dry etching residue removing solution according to any one of aspects 1 to 7.

Aspect 10. The method for producing a semiconductor device according to aspect 9, wherein the semiconductor wafer is a semiconductor wafer containing a ruthenium-based metal.

### Effects of Invention

According to the present invention, it is possible to provide a dry etching residue removing solution which can remove a residue on a substrate by dry etching in a production process of a semiconductor device with high efficiency, is excellent in storage stability, and maintains smoothness of a surface of an object to be treated which will be described below.

### DESCRIPTION OF EMBODIMENTS

Hereinafter, the present invention will be described in detail. The following description is an example (representative example) of the present invention, and the present invention is not limited thereto. In addition, the present invention can be modified and implemented in any manner that does not depart from the gist of the present invention. The dry etching residue removing solution according to an embodiment of the present invention is characterized by being a composition containing a specific metal described below. In the present invention, the dry etching residue removing solution (i.e., a chemical solution used for removing a residue after dry etching) is also described as a residue removing solution.

### Object to be Treated

An object to be treated (etching target) to which the residue removing solution according to an embodiment of the present invention is applied is a semiconductor wafer containing a transition metal. A method for producing the object to be treated is not particularly limited. For example, the object to be treated is obtained by the following method. A substrate such as silicon is subjected to oxidation treatment to form a silicon oxide film on the substrate, and an interlayer insulating film is formed thereon. In addition, a photoresist film is formed on the interlayer insulating film, and a via hole is formed in the interlayer insulating film. A metal film is formed in the formed via hole.

Examples of the transition metal include tantalum, silicon, copper, hafnium, zirconium, aluminum, vanadium, cobalt, nickel, manganese, gold, rhodium, palladium, titanium, tungsten, molybdenum, platinum, iridium, and ruthenium, and an oxide, a nitride, or a silicide thereof can be included. From the viewpoint of high electromigration resistance and a low resistance value, tungsten, cobalt, molybdenum, or ruthenium is preferable, and ruthenium is particularly preferable.

The metal film included in the object to be treated can be formed through any method, and for example, CVD, ALD, PVD, sputtering, or plating can be used.

### (Dry Etching Residue)

The dry etching residue is a by-product generated by dry etching and is a portion of the object to be treated described above. Examples thereof include an Si-containing residue, a metal-containing residue, and a photoresist-derived organic substance-containing residue.

### (Dry Etching Residue Removing Solution)

The dry etching residue removing solution (residue removing solution) of the present invention refers to a chemical solution used for removing a residue generated on a substrate by performing dry etching. The residue removing solution according to an embodiment of the present invention contains: one or more oxidizing agents selected from the group consisting of a hypobromite ion, a bromite ion, a hypochlorite ion, and a chlorate ion; a specific metal described below; and water.

The hypochlorite ion and the hypobromite ion are oxidizing agents with strong oxidation properties, and the residue removing solution according to an embodiment of the present invention containing the hypochlorite ion or the hypobromite ion can etch a transition metal at a high rate under alkaline conditions.

In a case where the object to be treated is ruthenium, generation of RuO₄ gas during etching can be suppressed. As a result, not only wafer processing efficiency per unit time is improved, but also reduction in yield due to RuO₂ particles is suppressed, and processing safe to a human body becomes possible. Thus, both the production cost and the safety are attained. Moreover, when pH, and a type and a concentration of the oxidizing agent are appropriately selected, ruthenium can be etched at a stable etching rate while suppressing the generation of RuO₄ gas.

### (Oxidizing Agent)

When the dry etching residue removing solution according to an embodiment of the present invention contains the oxidizing agent, it becomes possible to add a function of removing a metal contained in the dry etching residue. In addition, when the oxidizing agent is contained in the dry etching residue removing solution having alkalinity, the residue removing solution has an effect of decomposing and peeling an organic substance-containing residue. Further, surface potentials of an insoluble inorganic substance-containing residue and the object to be treated are negatively charged in an alkaline aqueous solution, and thus, an effect of preventing the insoluble inorganic substance-containing residue from re-adhering to the substrate or the like is obtained by action of electrostatic repulsion.

The type of the oxidizing agent is not particularly limited, but examples thereof include hydrogen peroxide, ozone, hypochlorous acid, chlorous acid, chloric acid, perchloric acid, hypobromous acid, bromous acid, bromic acid, perbromic acid, hypoiodous acid, iodous acid, iodic acid, periodic acid (ortho-periodic acid and meta-periodic acid), salts thereof, and ions produced by dissociation of these salts; and furthermore, one or more selected from the group consisting of hydrogen peroxide, ozone, fluorine, chlorine, bromine, iodine, permanganates, chromates, dichromates, and cerium salts. Among them, a hypobromite ion, a bromite ion, a bromate ion, a hypochlorite ion, a chlorite ion, a chlorate ion, a hypoiodous acid ion, an iodite ion, an iodate ion, and a periodate ion are preferable, a hypobromite ion, a bromate ion, a bromite ion, a hypochlorite ion, a chlorate ion, and a chlorite ion are more preferable, a hypobromite ion, a bromite ion, a hypochlorite ion, and a chlorate ion are still more preferable, from the viewpoints of high oxidaizing power, stability, and suitable use for semiconductor applications.

A concentration of the oxidizing agent in the residue removing solution according to an embodiment of the present invention is not particularly limited as long as it does not depart from the object of the present invention. The concentration is, for example, 0.0001 mol/L or more and 0.50 mol/L or less, and is preferably 0.0001 mol/L or more and 0.40 mol/L or less. With the concentration less than 0.0001 mol/L, the dry etching residue removing efficiency is low, reducing practicality. On the other hand, with the concentration higher than 0.50 mol/L, the oxidizing agent is easily decomposed, and thus the dry etching residue removing efficiency may be less likely to be stable.

One or plurality of oxidizing agents can be contained in the residue removing solution according to an embodiment of the present invention. In a case where a plurality of oxidizing agents are contained, a type of oxidizing agent as a second oxidizing agent different from a first oxidizing agent is not particularly limited, but examples thereof include: hydrogen peroxide, ozone, hypochlorous acid, chlorous acid, chloric acid, perchloric acid, hypobromous acid, bromous acid, bromic acid, perbromic acid, hypoiodous acid, iodous acid, iodic acid, periodic acid, salts thereof, and ions produced by dissociation of these salts; and furthermore, one or more selected from the group consisting of hydrogen peroxide, ozone, fluorine, chlorine, bromine, iodine, permanganates, chromates, dichromates, and cerium salts. Note that examples of the first oxidizing agent include a hypobromite ion and a hypochlorite ion.

Containing a plurality of oxidizing agents may stabilize a residue removing rate or improve the stability when the residue removing solution is reused. For example, in a case where a hypobromite ion is contained as a first oxidizing agent, a hypobromite ion consumed in etching a metal loses its oxidizing power and changes into a bromide ion. In this case, the greater the amount changing into a bromide ion, the more the residue removing ability decreases. In a semiconductor wafer production plant, a treatment liquid is commonly recycled and reused from the viewpoint of cost reduction. However, a decrease in the residue removing ability due to the reuse of the treatment liquid makes it difficult to stably produce semiconductor wafers. On the other hand, in a case where the residue removing solution contains a plurality of oxidizing agents, for example, when a hypochlorite ion is contained in addition to a hypobromite ion, a bromide ion losing its oxidizing power is oxidized with the hypochlorite ion and changes into a hypobromite ion. This makes it possible to suppress the decrease in the hypobromite ion concentration in the residue removing solution, and the etching rate is less likely to decrease even in a case of reusing the residue removing solution. Further, when a plurality of oxidizing agents are contained in the residue removing solution according to an embodiment of the present invention, the total concentration of the oxidizing agents is desirably 0.0001 mol/L or more and 0.40 mol/L or less.

### (Counter Cation of Oxidizing Agent)

A counter cation of the oxidizing agent is not particularly limited, and is preferably a metal ion or an onium ion described below. Examples of the metal ion include a calcium ion, a sodium ion, a potassium ion, a magnesium ion, an iron ion, a chromium ion, a nickel ion, a zinc ion, a copper ion, and an aluminum ion. In production of semiconductors, when a metal or a metal ion remains on a semiconductor wafer, there is a possibility that abnormality occurs in electrical characteristics or a processed shape. Thus, it is desirable that neither metal nor metal ion is contained as possible, and as the counter cation of the oxidizing agent, an onium ion is preferable.

### (Hypobromite Ion)

The hypobromite ion can be generated in the residue removing solution or can be added as a hypobromite salt to the residue removing solution. The hypobromite salt referred to here is a salt containing the hypobromite ion or a solution containing the salt containing the hypobromite ion. To generate hypobromite ions (BrO⁻, also described as BrO) in the residue removing solution, for example, bromine gas only has to be blown into the residue removing solution. In this case, from the viewpoint of efficiently generating hypobromite ions, the residue removing solution is preferably at 50° C. or lower. When the residue removing solution is at 50° C. or lower, not only hypobromite ions can be generated efficiently but also the generated hypobromite ions can be stably used for dry etching residue removal. Furthermore, to dissolve more bromine in the residue removing solution, the temperature of the residue removing solution is more preferably at 30° C. or lower and most preferably at 25° C. or lower. The lower limit of the temperature of the residue removing solution is not particularly limited, but the residue removing solution preferably does not freeze. Thus, the residue removing solution is preferably at −35° C. or higher, more preferably at −15° C. or higher, and most preferably at 0° C. or higher. The pH of the residue removing solution into which the bromine gas is blown is not particularly limited, but when the pH of the residue removing solution is alkaline, the residue removing solution is available for dry etching residue removal immediately after the generation of the hypobromite ions.

Furthermore, in a case where hypobromite ions are generated by blowing bromine gas into the residue removing solution, when the residue removing solution contains bromide ions (Br⁻), the solubility of bromine gas (Br₂) is improved. This is because Br₂ dissolved in the residue removing solution reacts with Br⁻ and Br₃⁻ to form a complex ion, such as Br₃⁻ or Br₅⁻, which is stabilized in the residue removing solution. The residue removing solution containing a large amount of Br₂, Br⁻, Br₃⁻, or Br₅⁻ can generate more hypobromite ions and thus can be suitably used as the residue removing solution according to an embodiment of the present invention.

It is also possible to produce hypobromite ions in the residue removing solution by oxidizing a bromine-containing compound with an oxidizing agent.

To add hypobromite ions as a compound to the residue removing solution, hypobromous acid, bromine water, and/or a hypobromite salt only has to be added. The hypobromite salt is suitably sodium hypobromite, potassium hypobromite, or a tetraalkylammonium hypobromite. From the viewpoint of substantial absence of a metal ion, which is otherwise problematic in semiconductor production, hypobromous acid or a tetraalkylammonium hypobromite is more suitable.

The tetraalkylammonium hypobromite described above is easily obtained by causing bromine gas to pass through a tetraalkylammonium hydroxide solution. In addition, the tetraalkylammonium hypobromite is also formed by mixing hypobromous acid and a tetraalkylammonium hydroxide solution. Furthermore, the tetraalkylammonium hypobromite can also be formed by substituting a cation contained in a hypobromite salt, such as sodium hypobromite, with a tetraalkylammonium ion using an ion exchange resin.

A concentration of the hypobromite ions in the residue removing solution according to an embodiment of the present invention is not particularly limited as long as the residue removing solution does not depart from the object of the present invention, but the concentration thereof is preferably 0.001 mol/L or more and 0.20 mol/L or less in terms of the hypobromite ions. With the concentration less than 0.001 mol/L, the dry etching residue removing efficiency is low, reducing practicality. On the other hand, with the concentration higher than 0.20 mol/L, a hypobromite ion is easily decomposed, and thus the dry etching residue removing efficiency is less likely to be stable. For stable dry etching residue removal at a sufficient rate, the concentration of the hypobromite ions is preferably 0.001 mol/L or more and 0.20 mol/L or less, more preferably 0.005 mol/L or more and 0.20 mol/L or less, and most preferably 0.01 mol/L or more and 0.10 mol/L or less.

To moderate the decrease in dry etching residue removing ability and to stabilize the dry etching residue removing efficiency, a proportion of the hypobromite ions in 1 mol of the bromine element contained in the residue removing solution preferably exceeds 0.5 mol. As described above, the hypobromite ion is easily changed to Br⁻ by an oxidation reaction or a decomposition reaction of ruthenium. Br does not etch a metal-containing residue, and thus it is important for stable dry etching residue removal that Br in the residue removing solution is rapidly oxidized to hypobromite ions and a concentration of chemical species (hypobromite ions; BrO⁻) having high dry etching residue removing ability is kept high. In a case where a proportion of hypobromite ions in 1 mol of the bromine element contained in the residue removing solution according to an embodiment of the present invention exceeds 0.5 mol, that is, in a case where more than half of all the bromine element in the residue removing solution is present as BrO⁻, the concentration of chemical species having the dry etching removing ability can be regarded as sufficiently high, and the dry etching residue removing efficiency is stabilized.

The concentration of the hypobromite ions in the residue removing solution can be confirmed using a widely known method. For example, using ultraviolet-visible absorption spectroscopy, absorption due to hypobromite ions can be easily observed and the hypobromite ion concentration can be determined from the intensity of the absorption peak (generally at or near 330 nm although this depends on the pH of the residue removing solution and the hypobromite ion concentration). Furthermore, the hypobromite ion concentration can also be determined by iodine titration. In addition, the hypobromite ion concentration can be determined from the oxidation-reduction potential (ORP) of the residue removing solution. The measurement by ultraviolet-visible absorption spectroscopy is most preferred from the viewpoint of enabling contactless and continuous measurement. In measuring the hypobromite ion concentration by ultraviolet-visible absorption spectroscopy, when absorption due to another chemical species is present, the hypobromite ion concentration can be determined with sufficient accuracy by data processing, such as spectral splitting or baseline correction, properly selecting the reference, or the like.

### (Bromite Ion)

In a case where the dry etching residue removing solution according to an embodiment of the present invention contains bromite ions (also described as BrO₂⁻ and BrO₂), when the concentration thereof is 0.0001 mol/L or more and 0.40 mol/L or less, storage stability of the chemical solution can be improved.

The concentration of the bromite ions in the residue removing solution according to an embodiment of the present invention is not particularly limited as long as the residue removing solution does not depart from the object of the present invention, but the concentration thereof is preferably 0.001 mol/L or more and 0.20 mol/L or less in terms of the amount of bromite ions. With the concentration less than 0.001 mol/L, the dry etching residue removing efficiency is low, reducing practicality. On the other hand, with the concentration higher than 0.20 mol/L, a bromite ion would be easily decomposed, and thus the dry etching residue removing efficiency is less likely to be stable. For stable dry etching residue removal at a sufficient rate, the concentration of the bromite ions is preferably 0.001 mol/L or more and 0.20 mol/L or less, more preferably 0.001 mol/L or more and 0.10 mol/L or less, and most preferably 0.001 mol/L or more and 0.05 mol/L or less.

Bromite ions can be generated in the residue removing solution or can be added as a bromite salt to the residue removing solution. The bromite salt referred to here is a salt containing the bromite ion or a solution containing the salt containing the bromite ion.

Alternatively, bromite ions can be produced in the residue removing solution by oxidizing a bromine-containing compound with an oxidizing agent.

To add bromite ions as a compound to the residue removing solution, bromous acid, bromine water, and/or a bromite salt only has to be added. The bromite salt is suitably sodium bromite, potassium bromite, or a tetraalkylammonium bromite. From the viewpoint of substantial absence of a metal ion, which is otherwise problematic in semiconductor production, bromous acid or a tetraalkylammonium bromite is more suitable.

A concentration of the bromite ions in the residue removing solution can be confirmed using a widely known method. For example, when ultraviolet-visible absorption spectroscopy is used, absorption due to bromite ions can be easily observed and the bromite ion concentration can be determined from the intensity of the absorption peak (generally at or near 298 nm although this depends on the pH of the residue removing solution and the bromite ion concentration). Furthermore, the bromite ion concentration can also be determined by iodine titration. In addition, the bromite ion concentration can be determined from the oxidation-reduction potential (ORP) of the residue removing solution. The measurement by ultraviolet-visible absorption spectroscopy is most preferred from the viewpoint of enabling contactless and continuous measurement. Note that in measuring the bromite ion concentration by ultraviolet-visible absorption spectroscopy, in a case where absorption due to another chemical species is present, the bromite ion concentration can be determined with sufficient accuracy by data processing, such as spectral splitting or baseline correction, properly selecting the reference, or the like.

### (Bromate Ion)

In a case where the dry etching residue removing solution according to an embodiment of the present invention contains bromate ions (also described as BrO₃⁻ and BrO₃), when the concentration thereof is 0.0001 mol/L or more and 0.40 mol/L or less, the storage stability of the chemical solution can be improved.

The concentration of the bromate ions in the residue removing solution according to an embodiment of the present invention is not particularly limited as long as the residue removing solution does not depart from the object of the present invention, but the concentration thereof is preferably 0.001 mol/L or more and 0.20 mol/L or less in terms of the amount of bromate ions. With the concentration less than 0.001 mol/L, the dry etching residue removing efficiency is low, reducing practicality. On the other hand, with the concentration higher than 0.20 mol/L, a bromate ion is easily decomposed, and thus the dry etching residue removing efficiency is less likely to be stable. For stable dry etching residue removal at a sufficient rate, the concentration of the bromate ion is preferably 0.001 mol/L or more and 0.20 mol/L or less, more preferably 0.001 mol/L or more and 0.10 mol/L or less, and most preferably 0.001 mol/L or more and 0.05 mol/L or less.

Bromate ions can be generated in the residue removing solution or can be added as a bromate salt to the residue removing solution. The bromate salt referred to here is a salt containing the bromate ion or a solution containing the salt containing the bromate ion.

It is also possible to produce bromate ions in the residue removing solution by oxidizing a bromine-containing compound with an oxidizing agent.

To add bromate ions as a compound to the residue removing solution, bromic acid, bromine water, and/or a bromate salt only has to be added. The bromate salt is suitably sodium bromate, potassium bromate, or a tetraalkylammonium bromate. From the viewpoint of absence of a metal ion, which is otherwise problematic in semiconductor production, bromic acid or a tetraalkylammonium bromate is more suitable.

The concentration of the bromate ions in the residue removing solution can be confirmed using a widely known method. For example, when ion chromatography analysis is used, a peak of bromate ion can be easily confirmed, and the bromate ion concentration in the solution can be determined from an intensity and a peak area of the absorption peak. In addition, the bromate ion concentration can be determined from the oxidation-reduction potential (ORP) of the residue removing solution, liquid chromatography mass spectrometry (LC/MS), or tandem mass spectrometry (LC/MS/MS).

### (Hypochlorite Ion)

In a case where the dry etching residue removing solution according to an embodiment of the present invention contains hypochlorite ions (ClO⁻, also described as ClO), when the concentration thereof is 0.001 mol/L or more and 0.40 mol/L or less, the storage stability of the chemical solution can be improved.

Hypochlorite ions can be generated in the residue removing solution or can be added as a hypochlorite salt to the residue removing solution. The hypochlorite salt referred to here is a salt containing the hypochlorite ion or a solution containing the salt containing the hypochlorite ion. To generate hypochlorite ions in the residue removing solution, for example, chlorine gas only has to be blown into the residue removing solution. In this case, from the viewpoint of efficiently generating hypochlorite ions, the residue removing solution is preferably at 50° C. or lower. When the residue removing solution is at 50° C. or lower, not only hypochlorite ions can be generated efficiently but also the generated hypochlorite ions can be stably used for dry etching residue removal. Furthermore, to dissolve more chlorine in the residue removing solution, the temperature of the residue removing solution is more preferably 30° C. or lower and most preferably 25° C. or lower. The lower limit of the temperature of the residue removing solution is not particularly limited, but the residue removing solution preferably does not freeze. Thus, the residue removing solution is preferably at −35° C. or higher, more preferably at −15° C. or higher, and most preferably at 0° C. or higher. The pH of the residue removing solution into which the chlorine gas is blown is not particularly limited, but when the pH of the residue removing solution is alkaline, the residue removing solution is available for dry etching residue removal immediately after the generation of the hypochlorite ions.

Furthermore, in a case where hypochlorite ions are generated by blowing chlorine gas into the residue removing solution, when the residue removing solution contains chloride ions (Cl⁻), the solubility of chlorine gas (Cl₂) is improved. This is because Cl₂ dissolved in the residue removing solution reacts with Cl⁻ and Cl₃⁻ to form a complex ion, such as Cl₃⁻ or Cl₅⁻, which is stabilized in the residue removing solution. The residue removing solution containing a large amount of Cl₂, Cl⁻, Cl₃⁻, or Cl₅⁻ can generate more hypochlorite ions and thus can be suitably used as the residue removing solution according to an embodiment of the present invention.

It is also possible to produce hypochlorite ions in the residue removing solution by oxidizing a chlorine-containing compound with an oxidizing agent.

To add hypochlorite ions as a compound to the residue removing solution, hypochlorous acid, chlorine water, and/or a hypochlorite salt only has to be added. The hypochlorite salt is suitably sodium hypochlorite, potassium hypochlorite, or a tetraalkylammonium hypochlorite. From the viewpoint of substantial absence of a metal ion, which is otherwise problematic in semiconductor production, hypochlorous acid or a tetraalkylammonium hypochlorite is more suitable.

The tetraalkylammonium hypochlorite is easily formed by causing chlorine gas to pass through a tetraalkylammonium hydroxide solution. In addition, the tetraalkylammonium hypochlorite is also formed by mixing hypochlorous acid and a tetraalkylammonium hydroxide solution. Furthermore, the tetraalkylammonium hypochlorite can also be formed by substituting a cation contained in a hypochlorite salt, such as sodium hypochlorite, with a tetraalkylammonium ion using an ion exchange resin.

The concentration of the hypochlorite ions in the residue removing solution is not particularly limited as long as the residue removing solution does not depart from the object of the present invention, but the concentration thereof is preferably 0.001 mol/L or more and 0.40 mol/L or less in terms of the hypochlorite ions. With the concentration less than 0.001 mol/L, the dry etching residue removing efficiency is low, reducing practicality. On the other hand, with the concentration higher than 0.40 mol/L, a hypochlorite ion is easily decomposed, and thus, the dry etching residue removing efficiency is less likely to be stable. For stable dry etching residue removal at a sufficient rate, the concentration of the hypochlorite ion is preferably 0.001 mol/L or more and 0.40 mol/L or less, more preferably 0.01 mol/L or more and 0.30 mol/L or less, and most preferably 0.1 mol/L or more and 0.20 mol/L or less.

The concentration of the hypochlorite ions in the residue removing solution can be confirmed using a widely known method. For example, using ultraviolet-visible absorption spectroscopy, absorption due to hypochlorite ions can be easily observed and the hypochlorite ion concentration can be determined from the intensity of the absorption peak (generally at or near 292 nm although this depends on the pH of the residue removing solution and the hypochlorite ion concentration). Furthermore, the hypochlorite ion concentration can also be determined by iodine titration. In addition, the hypochlorite ion concentration can be determined from the oxidation-reduction potential (ORP) and pH of the residue removing solution. The measurement by ultraviolet-visible absorption spectroscopy is most preferred from the viewpoint of enabling contactless and continuous measurement. Note that in measuring the hypochlorite ion concentration by ultraviolet-visible absorption spectroscopy, in a case where absorption due to another chemical species is present, the hypochlorite ion concentration can be determined with sufficient accuracy by data processing, such as spectral splitting or baseline correction, properly selecting the reference, or the like.

### (Chlorite Ion)

In a case where the dry etching residue removing solution according to an embodiment of the present invention contains a chlorite ion (also described as ClO₂⁻ or ClO₂), when the concentration thereof is 0.0001 mol/L or more and 0.40 mol/L or less, the storage stability of the chemical solution can be improved.

The concentration of the chlorite ions in the residue removing solution is not particularly limited as long as the residue removing solution does not depart from the object of the present invention, but the concentration thereof is preferably 0.001 mol/L or more and 0.20 mol/L or less in terms of the amount of chlorite ions. With the concentration less than 0.001 mol/L, the dry etching residue removing efficiency is low, reducing practicality. On the other hand, with the concentration higher than 0.20 mol/L, a chlorite ion is easily decomposed, and thus the dry etching residue removing efficiency is less likely to be stable. For stable dry etching residue removal at a sufficient rate, the concentration of the chlorite ion is preferably 0.001 mol/L or more and 0.20 mol/L or less, more preferably 0.001 mol/L or more and 0.10 mol/L or less, and most preferably 0.001 mol/L or more and 0.05 mol/L or less.

Chlorite ions can be generated in the residue removing solution or can be added as a chlorite salt to the residue removing solution. The chlorite salt referred to here is a salt containing the chlorite ion or a solution containing the salt containing the chlorite ion.

It is also possible to produce chlorite ions in the residue removing solution by oxidizing a chlorine-containing compound with an oxidizing agent.

To add chlorite ions as a compound to the residue removing solution, chlorous acid, chlorine water, and/or a chlorite salt only has to be added. The chlorite salt is suitably sodium chlorite, potassium chlorite, or a tetraalkylammonium chlorite. From the viewpoint of substantial absence of a metal ion, which is otherwise problematic in semiconductor production, chlorous acid or a tetraalkylammonium chlorite is more suitable.

The concentration of the chlorite ions in the residue removing solution can be determined using a widely known method. For example, when ion chromatography analysis is used, a peak of the chlorite ion can be easily confirmed, and the chlorite ion concentration in the solution can be determined from an intensity of the absorption peak and a peak area.

### (Chlorate Ion)

In a case where the dry etching residue removing solution according to an embodiment of the present invention contains chlorate ions (CO₃⁻, also described as ClO₃), when the concentration thereof is 0.0001 mol/L or more and 0.40 mol/L or less, the storage stability of the chemical solution can be improved.

The concentration of the chlorate ions in the residue removing solution according to an embodiment of the present invention is not particularly limited as long as the residue removing solution does not depart from the object of the present invention, but the concentration thereof is preferably 0.001 mol/L or more and 0.20 mol/L or less in terms of the amount of chlorate ions. With the concentration less than 0.001 mol/L, the dry etching residue removing efficiency is low, reducing practicality. On the other hand, with the concentration higher than 0.20 mol/L, a chlorate ion is easily decomposed, and thus the dry etching residue removing efficiency is less likely to be stable. For stable dry etching removing efficiency at a sufficient rate, the concentration of the chlorate ion is preferably 0.001 mol/L or more and 0.20 mol/L or less, more preferably 0.001 mol/L or more and 0.10 mol/L or less, and most preferably 0.001 mol/L or more and 0.05 mol/L or less.

Chlorate ions can be generated in the residue removing solution or can be added as a chlorate salt to the residue removing solution. The chlorate salt referred to here is a salt containing the chlorate ion or a solution containing the salt containing the chlorate ion.

It is also possible to produce chlorate ions in the residue removing solution by oxidizing a chlorine-containing compound with an oxidizing agent.

To add chlorate ions as a compound to the residue removing solution, chloric acid and/or a chlorate salt only has to be added. The chlorate salt is suitably sodium chlorate, potassium chlorate, or a tetraalkylammonium chlorate. From the viewpoint of absence of a metal ion, which is otherwise problematic in semiconductor production, chloric acid or a tetraalkylammonium chlorate is more suitable.

The concentration of the chlorate ions in the residue removing solution can be confirmed using a widely known method. For example, when ion chromatography analysis is used, a peak of the chlorate ion can be easily confirmed, and the chlorate ion concentration in the solution can be determined from an intensity of the absorption peak and a peak area. In addition, the chlorate ion concentration can be determined from the oxidation-reduction potential (ORP) of the residue removing solution.

### (pH of Dry Etching Residue Removing Solution)

An acid dissociation constant (pKₐ) of hypobromous acid (HBrO) and the hypobromite ion (BrO⁻) is 8.6, and an acid dissociation constant (pKₐ) of hypochlorous acid (HClO) and the hypochlorite ion (ClO⁻) is 7.5. Thus, there may be a case where HBrO and BrO⁻ or HClO and ClO⁻ coexist depending on the pH of the residue removing solution, such as at low pH. In a case of the residue removing solution containing HBrO and BrO⁻, the total concentration of HBrO and BrO⁻ only has to be used as the concentration of the hypobromite ions. Similarly, in a case of the residue removing solution containing HClO and ClO⁻, the total concentration of HClO and ClO⁻ only has to be used as the concentration of the hypochlorite ions.

To adjust the pH of the residue removing solution, an acid or an alkali can be added to the residue removing solution. The acid can be either an inorganic acid or an organic acid, and examples thereof includes hydrofluoric acid, hydrochloric acid, hydrobromic acid, nitric acid, acetic acid, sulfuric acid, and peroxodisulfuric acid; and a carboxylic acid, such as formic acid and acetic acid, but in addition to these, a widely known acid used in a residue removing solution for a semiconductor can be used without any limitation. For the alkali, an organic alkali is preferably used because it does not contain a metal ion, which is otherwise problematic in semiconductor manufacturing. An example of the organic alkali is a tetraalkylammonium hydroxide including a tetraalkylammonium ion and a hydroxide ion. Examples of the tetraalkylammonium hydroxide include tetramethylammonium hydroxide, tetraethylammonium hydroxide, tetrapropylammonium hydroxide, tetrabutylammonium hydroxide, ethyltrimethylammonium hydroxide, and propyltrimethylammonium hydroxide. In particular, the organic alkali is preferably tetraalkylammonium hydroxide and more preferably tetramethylammonium hydroxide because it provides a large number of hydroxide ions per unit weight and a high-purity product is readily available.

One type of the tetraalkylammonium ions can be contained in the residue removing solution, or a plurality of types may be used in combination.

### (Metal Contained in Dry Etching Residue Removing Solution)

When the dry etching residue removing solution contains one or more metals selected from the group consisting of Mg, Ca, Na, and K in an amount of 0.01 ppt or more and 1000 ppt or less as the specific metals, the dry etching residue removing solution is further effective in maintaining surface smoothness of the object to be treated.

Although the mechanism is not clear, it is considered that the target mixture is adsorbed on the surface of the transition metal-containing material to make the electronic state uniform. Thus, when the residue removing solution contains one or more metals selected from the group consisting of Mg, Ca, Na, and K, the residue removing solution has an effect of maintaining the surface smoothness of the object to be treated. The total content of one or more metals selected from the group consisting of Mg, Ca. Na, and K contained in the residue removing solution is 0.01 ppt or more and 1000 ppt or less, more preferably 0.01 ppt or more and 200 ppt or less, and even more preferably 0.01 ppt or more and 50 ppt or less.

Note that the dry etching residue removing solution may contain only Mg; only Ca; only Na; only K; Mg, Ca, Na, and K; only Mg, Ca, and Na; only Mg, Ca, and K; only Mg, Na, and K; only Ca, Na, and K; only Mg and Ca: only Mg and Na; only Mg and K; only Ca and Na; only Ca and K; or only Na and K. The content of the specific metal contained in the etching residue removing solution is the total of the contents of all the contained metals.

Depending on a production process, the dry etching residue removing solution may contain one or more metals selected from the group consisting of alkali metals and alkaline earth metals other than Mg, Ca, Na, and K, Fe, Cr, Ni, Zn, Cu, and Al. These do not contribute to the surface smoothness, but may be contained.

The dry etching residue removing solution according to an embodiment of the present invention may contain chloride ions, bromide ions, and iodide ions derived from the production process and raw materials thereof. The content thereof can be used without any problem as long as it is a concentration which does not affect the dry etching residue removal, and it is preferable that the concentration of each of them does not exceed 1 mass %.

### (Onium Ion)

When the residue removing solution contains an onium ion, it is effective in maintaining the surface smoothness. The surface of the object to be treated is also etched by a residue removing step, and thus it is required that the surface smoothness does not change before and after treatment. To maintain the surface smoothness of the object to be treated in a preferable range, it is preferable to select one or more types selected from the group consisting of onium ions having structures represented by the following Formulae (1) to (6).

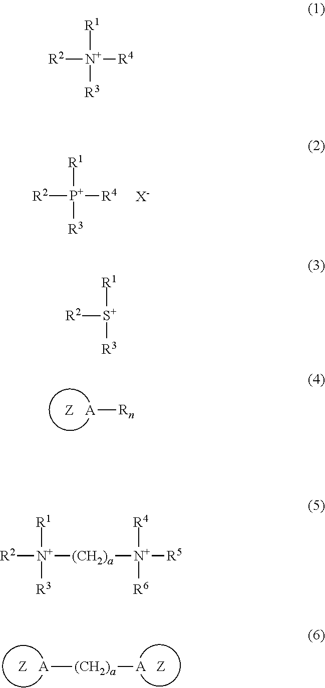

In Formula (1) to Formula (6),

R¹, R², R³, R⁴, R⁵, and R⁶ are independently an alkyl group having a carbon number from 2 to 9, an allyl group, an aralkyl group having an alkyl group having a carbon number from 1 to 9, or an aryl group. In addition, in an aryl group of the aralkyl group and in a ring of the aryl group, at least one hydrogen is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9, and in these groups, at least one hydrogen is optionally substituted with fluorine, chlorine, bromine, or iodine.

Examples of the counter anion to the onium ion include a fluoride ion, a chloride ion, a bromide ion, an iodide ion, a hydroxide ion, a nitrate ion, a phosphate ion, a sulfate ion, a hydrogensulfate ion, a methanesulfate ion, a perchlorate ion, a chlorate ion, a chlorite ion, a hypochlorite ion, a perbromate ion, a bromate ion, a bromite ion, a hypobromite ion, an orthoperiodate ion, a metaperiodate ion, an iodate ion, an iodite ion, a hypoiodite ion, an acetate ion, a carbonate ion, a hydrogen carbonate ion, a fluoroborate ion, or a trifluoroacetate ion.

A is an ammonium ion or a phosphonium ion.

Z is an aromatic group or alicyclic group optionally comprising a nitrogen, sulfur, or oxygen atom, and in the aromatic group or alicyclic group, carbon or nitrogen optionally has chlorine, bromine, fluorine, iodine, at least one alkyl group having a carbon number from 1 to 9, at least one alkenyloxy group having a carbon number from 2 to 9, an aromatic group optionally substituted with at least one alkyl group having a carbon number from 1 to 9, or an alicyclic group optionally substituted with at least one alkyl group having a carbon number from 1 to 9.

R is chlorine, bromine, fluorine, iodine, an alkyl group having a carbon number from 1 to 9, an allyl group, an aromatic group optionally substituted with at least one alkyl group having a carbon number from 1 to 9, or an alicyclic group optionally substituted with at least one alkyl group having a carbon number from 1 to 9. n is an integer of 1 or 2 and represents the number of R. When n is 2, Rs are optionally the same or different and optionally form a ring, a is an integer of 1 to 10.

With a longer chain length, the hydrocarbon group represented by R in the formulas has higher hydrophobicity. Thus, the surface tension tends to decrease in the residue removing solution containing an onium ion having a longer-chain hydrocarbon group. On the other hand, with too short a hydrocarbon chain, the effects of the onium ion, that is, an improvement in surface smoothness and the effect of suppressing RuO₄ gas, would be limited. For such a reason, the carbon number of the hydrocarbon group is preferably within the range described above.

When the residue removing solution contains an onium ion, generation of a gas due to a metal oxide can be suppressed. For example, in a case where the object to be treated is ruthenium, ruthenium is oxidized by the oxidizing agent in the residue removing solution to generate RuO₄⁻, RuO₄²⁻, or the like. The generated RuO₄⁻, RuO₄²⁻, or the like interacts with the onium ion to suppress the generation of RuO₄ gas.

### (Concentration of Onium Ion)

The concentration of the onium ion in the residue removing solution according to an embodiment of the present invention is preferably 1 mass ppm or more and 10000 mass ppm or less. With too small an addition amount of the onium ion, not only interaction with an object to be treated such as RuO₄⁻ weakens and the effect of suppressing RuO₄ gas decreases but also the amount of the onium ion adhering to the metal surface during residue removal is insufficient. Thus, the surface smoothness tends to decrease. On the other hand, with too large an addition amount, the amount of the onium ion adsorbed to the metal surface is too large, which reduces the residue removing rate. In addition, the oxidizing agent and the onium ion in the residue removing solution may react with each other and may cause a decrease in the concentration of the oxidizing agent. Thus, the residue removing solution according to an embodiment of the present invention contains the onium ion in an amount of preferably 1 mass ppm or more and 10000 mass ppm or less, more preferably 10 mass ppm or more and 5000 mass ppm or less, and even more preferably 50 mass ppm or more and 2000 mass ppm or less. Note that in the case of adding an onium ion, only one type can be added, or two or more types can be added in combination. Also in the case of containing two or more types of onium ions, with the total concentration of the onium ions in the above concentration range, the generation of RuO₄ gas can be effectively suppressed.

Examples of such onium ions include a chlorocholine ion, a bromocholine ion, a trans-2-butene-1,4-bis(triphenylphosphonium ion), a 1-hexyl-3-methylimidazolium ion, an allyltriphenylphosphonium ion, a tetraphenylphosphonium ion, a benzyltriphenylphosphonium ion, a methyltriphenylphosphonium ion, a (2-carboxyethyl)triphenylphosphonium ion, a (3-carboxypropyl)triphenylphosphonium ion, a (4-carboxybutyl)triphenylphosphonium ion, a (5-carboxypentyl)triphenylphosphonium ion, a cinnamyltriphenylphosphonium ion, a (2-hydroxybenzyl)triphenylphosphonium ion, a (1-naphthylmethyl)triphenylphosphonium ion, a butyltriphenylphosphonium ion, a (tert-butoxycarbonylmethyl)triphenylphosphonium ion, an allyltriphenylphosphonium ion, a (3-methoxybenzyl)triphenylphosphonium ion, a (methoxymethyl)triphenylphosphonium ion, a (1-ethoxy-1-oxopropan-2-yl)triphenylphosphonium ion, a (3,4-dimethoxybenzyl)triphenylphosphonium ion, a methoxycarbonylmethyl(triphenyl)phosphonium ion, a (2,4-dichlorobenzyl)triphenylphosphonium ion, a (2-hydroxy-5-methylphenyl)triphenylphosphonium ion, a (4-chlorobenzyl)triphenylphosphonium ion, a (3-chloro-2-hydroxypropyl)trimethylammonium ion, a methacroylcholine ion, a benzoylcholine ion, a benzyldimethylphenylammonium ion, a (2-methoxyethoxymethyl)triethylammonium ion, a carbamylcholine ion, a 1,1′-difluoro-2,2′-bipyridinium bis(tetrafluoroborate), a benzyltributylammonium ion, a trimethylphenylammonium ion, a 5-azoniaspiro[4.4]nonane ion, a tributylmethylammonium ion, a tetrabutylammonium ion, a tetrapentylammonium ion, a tetrabutylphosphonium ion, a diallyldimethylammonium ion, a 1,1-dimethylpiperidinium ion, a (2-hydroxyethyl)dimethyl(3-sulfopropyl)ammonium hydroxide, a 3-(trifluoromethyl)phenyltrimethylammonium ion, a 1,1′-(decane-1,10-diyl)bis[4-aza-1-azoniabicyclo[2.2.2]octane]diion, a (3-bromopropyl)trimethylammonium ion, vinylbenzyltrimethylammonium ion, an allyltrimethylammonium ion, a trimethylvinylammonium ion, a choline ion, a β-methylcholine ion, a triphenylsulfonium ion, ethyltrimethylammonium ion, and propyltrimethylammonium. The onium ion is preferably one or more types selected from the group consisting of a benzyldimethylphenylammonium ion, a 1-ethoxy-1-oxopropan-2-yl)triphenylphosphonium ion, a 1,1′-(decan-1,10-diyl)bis[4-aza-1-azoniabicyclo[2.2.2]octane]diion, a butyltriphenylphosphonium ion, a (2-carboxyethyl)triphenylphosphonium ion, a (3-carboxypropyl)triphenylphosphonium ion, a (4-carboxybutyl)triphenylphosphonium ion, an allyltriphenylphosphonium ion, a tetraphenylphosphonium ion, and a benzyltriphenylphosphonium ion.

As described above, the effects of the onium ion include suppression of surface roughening during residue removal and suppression of RuO₄ gas. In addition, the onium ion also has an effect of increasing the number of times of reuse in a case where the residue removing solution is used as a semiconductor residue removing solution. In a semiconductor wafer manufacturing plant, a used residue removing solution is sometimes circulation-filtered and reused from the viewpoint of cost reduction. In this case, for example, after residue removal, a metal dissolves in the residue removing solution, and thus the composition of the residue removing solution differs before and after use. When description is given using ruthenium residue removal by hypobromite ions as an example, ruthenium dissolves as RuO₄⁻ under alkaline conditions. In this case, when this RuO₄⁻, or RuO₄²⁻ or RuO₄ generated by the change of RuO₄⁻ reacts with the hypobromite ion, the concentration of the hypobromite ion, which is a chemical species effective for residue removal, decreases. Thus, the residue removal rate decreases with the increase in the number of times of reuse of the residue removing solution and with the increase in the reuse time.

However, when an onium ion is contained in the residue removing solution, the stability at the time of reuse may be improved. That is, RuO₄⁻ or the like actively reacts with the onium ion, and this makes it possible to suppress the reaction of RuO₄⁻ or the like with a hypobromite ion. The onium ion that can be used for such a purpose is preferably a phosphonium ion. An ammonium ion poses a concern that reaction with a hypobromite ion produces an amine, and thus this amine may decompose the hypobromite ion. In addition, a phosphonium ion generally has a larger molecular size than an ammonium ion and easily forms an ion pair with RuO₄⁻ generated by dissolution, thus binds RuO₄⁻ and also provides an effect of suppressing the reaction of RuO₄⁻ with a hypobromite ion.

In addition, it is preferable that the residue removing solution contains an onium ion and the residue removing solution has a surface tension of 60 mN/m or more and 75 mN/m or less. Note that the surface tension is a value at 25° C.

When the residue removing solution has a surface tension of 60 mN/m or more, the onium ion interacts with the metal surface of a semiconductor wafer, and this makes it possible to suppress roughening of the metal surface. On the other hand, the residue removing solution according to an embodiment of the present invention contains an oxidizing agent, and thus it is preferable that the surface tension is 75 mN/m or less to prevent the oxidizing agent from being unstable or to prevent the residue removal from being inhibited.

One method of increasing the surface tension of the residue removing solution is a method of adding a salt containing an anion with a high degree of hydration. Adding an anion with a high degree of hydration inhibits the neutralization of the charge of the onium ion by the anion and maintains the electrical repulsion between the onium ions, and thus can increase the surface tension. Examples of the anion with a high degree of hydration include a fluoride ion, a chloride ion, and a bromide ion.

The measurement of the surface tension was performed in accordance with “Test Method by Wilhelmy Surface Tensiometer” of JIS 2241.

Examples of such an onium ion include an allyltriphenylphosphonium ion, a tetraphenylphosphonium ion, a trans-2-butene-1,4-bis(triphenylphosphonium ion), a benzyltriphenylphosphonium ion, a tetrabutylphosphonium ion, a tributylhexylphosphonium ion, a heptyltriphenylphosphonium ion, a cyclopropyltriphenylphosphonium ion, a (bromomethyl)triphenylphosphonium ion, and a (chloromethyl)triphenylphosphonium ion.

(Case where Object to be Treated is Ruthenium)

Ruthenium (Ru), which is an example of the object to be treated in the present invention, may be a ruthenium-based metal or a ruthenium alloy.

When the object to be treated is a ruthenium-based metal and pH is 9.5 or higher and 14 or lower at 25° C., harmful RuO₄ gas is less likely to be generated and particles due to RuO₂ are also less.

Although the details of the mechanism in which hypobromite ions and hypochlorite ions dissolve ruthenium are not necessarily clear, it is speculated that the hypobromite ions or hypobromous acid generated from the hypobromite ions, or the hypochlorite ions or hypochlorous acid generated from the hypochlorite ions oxidizes the ruthenium to form RuO₄, RuO₄⁻ or RuO₄²⁻, and thereby the ruthenium is dissolved in the residue removing solution. Dissolving ruthenium as RuO₄⁻ or RuO₄²⁻ makes it possible to reduce the amount of RuO₄ gas to be generated and suppress the generation of RuO₂ particles. To dissolve the ruthenium as RuO₄⁻ or RuO₄²⁻, the pH of the residue removing solution is preferably 9.5 or higher and 14 or lower, more preferably 12 or higher and 14 or lower, and most preferably 12 or higher and lower than 13. With the pH of the residue removing solution of 12 or higher and lower than 13, the ruthenium is dissolved as RuO₄⁻ or RuO₄²⁻ in the residue removing solution, and thus the amount of RuO₄ gas generated is significantly reduced, and generation of RuO₂ particles can be suppressed. On the other hand, in a case where the pH of the residue removing solution is lower than 8, the ruthenium is easily oxidized to RuO₂ and RuO₄, and thus the amount of RuO₂ particles increases, and the amount of RuO₄ gas generated tends to increase. In addition, ruthenium is less likely to dissolve in the residue removing solution with a pH higher than 14, making it difficult to obtain a sufficient ruthenium etching rate, thus reducing the production efficiency in semiconductor production. Note that the pH values exemplified above are all values at 25° C.

Here, the “ruthenium-based metal” refers to metal ruthenium, ruthenium metal containing 70 atomic % or more of ruthenium, an oxide (RuO_{X}), a nitride (RuN), an oxynitride (RuNO), and the like of ruthenium. Here, the oxide of ruthenium means ruthenium dioxide or diruthenium trioxide (trihydrate). In addition, in the present invention, the “ruthenium alloy” refers to an alloy containing 70 atomic % or more and 99.99 atomic % or less of ruthenium and a metal other than ruthenium at a concentration higher than a concentration at which the other metal is unavoidably contained. In the present invention, when it is not necessary to particularly distinguish between a ruthenium-based metal and a ruthenium alloy, they are described as ruthenium.

The ruthenium alloy can contain any metal other than ruthenium. Examples of the metal contained in the ruthenium alloy include tantalum, silicon, copper, hafnium, zirconium, aluminum, vanadium, cobalt, nickel, manganese, gold, rhodium, palladium, titanium, tungsten, molybdenum, platinum, and iridium, and the ruthenium alloy can contain an oxide, a nitride, a carbide, or a silicide of these.

Such ruthenium can be an intermetallic compound, an ionic compound, or a complex. In addition, the ruthenium can be exposed at the surface of the wafer or covered with another metal, a metal oxide film, an insulating film, a resist, or the like. Even in a case of being covered with another material, when ruthenium comes into contact with the residue removing solution according to an embodiment of the present invention and dissolution of ruthenium occurs, the effect of suppressing generation of RuO₄ gas is exhibited. Furthermore, the residue removing solution according to an embodiment of the present invention can suppress RuO₄ gas generated from very slightly dissolved ruthenium in a case where ruthenium is not actively dissolved, that is, even in a treatment in which ruthenium is an object to be protected.

### (Method for Producing Semiconductor Device)

A method for producing a semiconductor device according to an embodiment of the present invention includes a step of dry-etching a semiconductor wafer, and a step of removing a dry etching residue with the dry etching residue removing solution described above. Furthermore, before the step of dry-etching a semiconductor wafer, a metal film forming step of forming a metal film on a semiconductor substrate to form the semiconductor wafer can be included, and before and/or after the step of removing a dry etching residue, a step of rinsing the semiconductor wafer and a step of drying the semiconductor wafer can be included.

When the dry etching residue removing solution is used after the step of dry-etching the semiconductor wafer (the step of dry-etching the metal film on the semiconductor substrate), the residue can be removed with higher efficiency as compared with a case of being treated only by dry-etching. In addition, the treatment can be performed without impairing the surface smoothness of the metal film surface as compared with a case of being treated only by wet-etching.

In the step of rinsing the semiconductor wafer, the semiconductor wafer can be cleaned by bringing a rinsing liquid into contact with the semiconductor wafer. The rinsing liquid can be selected from the group consisting of water, functional water such as ozone water, radical water, and electrolytic ion water, an organic solvent such as 2-propanol, an ammonia-hydrogen peroxide mixture, a hydrochloric acid-hydrogen peroxide mixture, a sulfuric acid-hydrogen peroxide mixture, a nitric acid-hydrofluoric acid mixture, hydrofluoric acid, sulfuric acid, phosphoric acid, nitric acid, buffered hydrofluoric acid, ammonia, hydrogen peroxide, hydrochloric acid, tetramethylammonium hydroxide (TMAH), and a mixture thereof with water.

The step of drying the semiconductor wafer is not particularly limited, and drying can be performed by spin drying, IPA drying, marangoni drying, Rotagoni drying, or the like.

The method for producing a semiconductor device can include a known step used in a method for producing a semiconductor device, such as one or more steps selected from a wafer fabrication step, an oxide film formation step, a transistor formation step, a wiring formation step, and a CMP step.

The substrate on which the dry etching is performed is a semiconductor wafer containing a transition metal. The transition metal film can be formed on the substrate through any method, and for example, CVD, ALD, PVD, sputtering, or plating can be used.

In a case of dry-etching the transition metal-containing semiconductor wafer prepared by the above-described method, the method of dry-etching is not particularly limited and can be performed by a known method, but it is preferable to perform dry-etching using an O₂/Cl₂ mixed gas.

The dry etching is preferably reactive ion etching. As a method of generating plasma for the reactive ion etching, a capacitive coupled plasma-RIE method, an inductive coupled plasma-RIE method, and an electron cyclotron resonance-RIE method are preferable.

When the dry etching is performed by the above-described method, dry etching residues such as Si-containing residues, metal-containing residues, and photoresist-derived organic substance-containing residues are generated. The residue removing solution according to an embodiment of the present invention is suitably used for removing these dry etching residues.

### (Dry Etching Residue Removing Method of Semiconductor Wafer and Cleaning Method of Semiconductor Wafer)

The residue removing solution according to an embodiment of the present invention is brought into contact with a semiconductor wafer, which can perform dry etching residue removal of the semiconductor wafer. That is, a dry etching residue removing method of a semiconductor wafer according to an embodiment of the present invention includes a step of bringing the residue removing solution into contact with a semiconductor wafer.

The dry etching residue removing method according to an embodiment of the present invention can also be used as a cleaning method of a semiconductor wafer. Similarly to the dry etching residue removing method, the cleaning method of a semiconductor wafer also includes a step of bringing the residue removing solution into contact with the semiconductor wafer.

In the dry etching residue removing method or the cleaning method of a semiconductor wafer, a method of bringing the residue removing solution into contact with the semiconductor wafer is not particularly limited, and only has to be appropriately selected depending on the cleaning conditions of a cleaning apparatus to be used and the semiconductor wafer to be used. Examples of the method include a method of spraying the residue removing solution onto the semiconductor wafer, a method of immersing the semiconductor wafer in a container containing the residue removing solution, a method of dropping the residue removing solution onto the semiconductor wafer, a method of bringing the residue removing solution into contact with the semiconductor wafer and applying ultrasonic waves to promote residue removal, and any combination thereof.

The temperature at which the residue removing solution according to an embodiment of the present invention is used is in a range of 10 to 80° C., preferably 20 to 70° C., and only has to be appropriately selected depending on the cleaning conditions of a cleaning apparatus to be used and a semiconductor wafer to be used.

The time for which the residue removing solution according to an embodiment of the present invention is used is 0.1 to 120 minutes, preferably 0.5 to 60 minutes per wafer, and only has to be appropriately selected depending on the cleaning conditions of a cleaning apparatus to be used and a semiconductor wafer to be used.

### (Storage Container)

A container in which the residue removing solution according to an embodiment of the present invention is stored is not particularly limited, but is preferably a highly clean container in which elution of impurities from the container is small. The inner surface of the container in contact with the solution is preferably made of an organic polymer material because elution of metal components is small. Examples of the organic polymer material that is used for the inner surface of the container include vinyl chloride-based resins (soft or hard vinyl chloride resins), nylon-based resins, silicone-based resins, polyolefin-based resins (polyethylene and polypropylene), and fluorine-based resins. Among them, in consideration of ease of molding, solvent resistance, small elution of impurities, and the like, a polyolefin-based resin or a fluororesin is preferable.

### Examples

The present invention will be more specifically described below by examples, but the present invention is not limited to these Examples.

### (Production of Semiconductor Device)

First, a substrate made of silicon was prepared. The prepared substrate was subjected to oxidation treatment to form 500 nm of a silicon oxide film on the silicon. Then, 50 nm of an interlayer insulating film made of a low dielectric constant (Low-k) film was formed, and a via hole was formed in the interlayer insulating film. A ruthenium film of 20 nm was formed on the formed via hole.

The object to be treated (semiconductor substrate) on which the ruthenium film was formed by the above-described method was subjected to dry etching treatment using a reactive ion etching apparatus (available from Samco Inc., RIE-400IPC).

The object to be treated dry-etched by the above method was cut into 10×20 mm. 60 mL of the dry etching residue removing solution was prepared in a fluororesin container with a lid (available from As One Corporation, PFA container 94.0 mL). The object to be treated after dry etching prepared by the above method was immersed in the dry etching residue removing solution at 30° C. for 1 minute.

60 mL of ultrapure water was prepared in a fluororesin container with a lid (available from As One Corporation, PFA container 94.0 mL). The semiconductor wafer after dry etching residue removal treatment prepared by the above method was immersed in ultrapure water at 30° C. for 1 minute.

The ultrapure water was removed by spraying dry nitrogen onto the semiconductor object to be treated obtained by the above method.

### (Evaluation of Dry Etching Residue Removal Rate by Residue Removing Solution)

The object to be treated after the dry etching treatment prepared by the above method was observed using a transmission electron microscope (TEM). The number a of dry etching residues was counted from the obtained image. Then, 60 mL of the dry etching residue removing solution was prepared in a fluororesin container with a lid (available from As One Corporation, PFA container 94.0 mL). The object to be treated prepared by the above method was immersed in the dry etching residue removing solution at 30° C. for 1 minute. Then, the object to be treated that had been treated by the dry etching residue removal was observed using a TEM. The number β of dry etching residues was counted from the obtained image. From the numbers α and β of dry etching residues obtained by this observation, a residue removal rate X (%) was calculated from an equation X=(α−β)/α×100, and evaluation was performed according to the following criteria. In any case, evaluations A to C are acceptable levels, and an evaluation D is an unacceptable level.

### Evaluation:

A: 90% or more
B: 70% or more and less than 90%
C: 50% or more and less than 70% (acceptable level)
D: less than 50%

### (Quantitative Analysis of RuO₄ Gas)

The generated amount of RuO₄ gas was measured using an ICP-OES. In a sealed container, 5 mL of the dry etching residue removing solution was placed, and one 10×20 mm ruthenium film obtained by forming a ruthenium film with a film thickness of 120 nm was immersed at 30° C. until all the ruthenium was dissolved. Then, air was flowed into the sealed container, the gas phase in the sealed container was bubbled into a container containing an absorbing liquid (1 mol/L NaOH), and the RuO₄ gas generated during immersion was trapped in the absorbing liquid. The dissolution of all the ruthenium on the Si wafer immersed in the dry etching residue removing solution was confirmed by measuring sheet resistances before and after immersion with a four-probe resistance meter (Loresta-GP, available from Mitsubishi Chemical Analytech Co., Ltd.) and converting the sheet resistances to film thicknesses. The ruthenium amount in the absorbing liquid was measured with an ICP-OES (iCAP6500 DUO, available from Thermo Fisher Scientific K.K.), converted to the RuO₄ gas amount, and evaluated according to the following criteria. In any case, evaluations A to C are acceptable levels, and an evaluation D is an unacceptable level.

### Evaluation:

A: <5 μg/cm²
B: from 5 to less than 10 μg/cm²
C: from 10 μg/cm² to 40 μg/cm² or less (acceptable level)
D: >40 μg/cm²

### (Evaluation of Storage Stability of Oxidizing Agent in Residue Removing Solution)

The storage stability of the oxidizing agent in the residue removing solution was evaluated using an ultraviolet-visible spectrophotometer (UV-2600, available from Shimadzu Corporation). 5 L of the dry etching residue removing solution was prepared in a light-shielding pure bottle (available from KODAMA PLASTICS CO., Ltd., PFA container 5 L) and stored at 25° C. while being shielded from light. Thereafter, the concentration of the oxidizing agent in the dry etching residue removing solution was periodically measured for 6 months using an ultraviolet-visible spectrophotometer (UV-2600, available from Shimadzu Corporation). The concentration of the oxidizing agent immediately after the production was taken as 100%, and the concentration of the oxidizing agent in the dry etching residue removing solution after 6 months was evaluated according to the following criteria. In any case, evaluations A to C are acceptable levels, and an evaluation D is an unacceptable level.

### Evaluation:

A: 95% or more
B: 90 or more and less than 95%
C: 85 or more and less than 90% (acceptable level)
D: less than 85%
   (Evaluation of Surface Smoothness after Etching)

60 mL of the dry etching residue removing solution was prepared in a fluororesin container with a lid (available from As One Corporation, PFA container 94.0 mL), and the object to be treated before the dry etching treatment prepared by the above-described method was immersed in the dry etching residue removing solution at 30° C. for 1 minute for etching. Thereafter, the ruthenium surface before and after etching was observed with a field emission scanning electron microscope (JSM-7800F Prime, available from JEOL Ltd.) to confirm the presence or absence of surface roughening and evaluation was performed according to the following criteria. Surface roughening was evaluated as A to D in the order of less to more roughening, and in any case, evaluations of A to C are acceptable levels, and an evaluation D is an unacceptable level.
A: no roughening of surface is observed
B: slight roughening of surface is observed
C: roughening is observed on the entire surface, but the roughness is shallow
D: roughening is observed on the entire surface, and the roughness is deep

### (Production of Residue Removing Solution)

In a 2-L glass three-necked flask (available from Cosmos Bead Co., Ltd.), 209 g of a 25 mass % tetramethylammonium hydroxide aqueous solution was mixed with 791 g of ultrapure water, and a 5.2 mass % tetramethylammonium hydroxide aqueous solution with a CO₂ content of 0.5 ppm. The pH at this time was 13.8.

A stirring bar (30 mm in total length×8 mm in diameter, available from As One Corporation) was then placed in the three-necked flask, and a thermometer protecting tube (bottom-sealed type, available from Cosmos Bead Co., Ltd.) and a thermometer were placed in one opening. From another opening, a PFA tube (F-8011-02, available from Flon Industry) connected to a chlorine gas cylinder and a nitrogen gas cylinder in a state where the chlorine gas and the nitrogen gas can be freely switched was inserted, and the end of the PFA tube was immersed in the bottom of the solution. The remaining one opening was connected to a gas-washing bottle (gas-washing bottle, model No. 2450/500, available from As One Corporation) filled with a 5 mass % sodium hydroxide aqueous solution. Then, nitrogen gas with a carbon dioxide concentration of less than 1 ppm was flowed from the PFA tube at 0.289 Pa·m³/sec (when converted to 0° C.) for 20 minutes, and carbon dioxide in the gas phase was purged. At this time, the carbon dioxide concentration in the gas phase was 1 ppm or less.

Then, a magnetic stirrer (C-MAG HS10, available from As One Corporation) was placed in the bottom portion of the three-necked flask and rotated at 300 rpm to stir the contents, and while the periphery of the three-necked flask was cooled with ice water, chlorine gas (specification purity 99.4%, available from Fujiox Co., Ltd.) was supplied at 0.059 Pa·m³/sec (when converted to 0° C.) for 180 minutes, and a mixed solution of a tetramethylammonium hypochlorite aqueous solution (oxidizing agent; 3.51 mass % equivalent, 0.28 mol/L) and tetramethylammonium hydroxide (0.09 mass % equivalent, 0.0097 mol/L) was obtained. At this time, the solution temperature during the reaction was 11° C.

Thereafter, 0.1 g of an aqueous sodium hydroxide solution (0.1 mol/L, available from Wako Pure Chemical Industries, Ltd.) was weighed into a 100 ml PFA bottle (available from As One Corporation, ACPFA100-N) and diluted to 100 ml. Further, 0.1 g of the diluted solution obtained by the above operation was weighed in a 100 ml PFA bottle (available from As One Corporation, ACPFA100-N) and diluted to 100 ml. Thus, a metal-containing solution was obtained.

The tetramethylammonium hypochlorite solution obtained by the above-described operation, ultrapure water, an onium salt, tetramethylammonium hydroxide (25 mass %, available from Tokuyama Corporation), hydrochloric acid, and the metal-containing solution obtained by the above-described operation were added and mixed to have the concentrations described in Tables 1 to 3, thereby obtaining residue removing solutions having the compositions described in Examples 19 to 29 and 40 to 42. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

To 97.02 g of ultrapure water were added 0.04 g of the tetramethylammonium hypochlorite solution obtained by the above operation, 0.01 g of tetramethylammonium bromide (97 mass %, available from Tokyo Chemical Industry Co., Ltd.), 0.05 g of (1-ethoxy-1-oxopropan-2-yl) triphenylphosphonium bromide (98 mass %, available from Tokyo Chemical Industry Co., Ltd.), 1.14 g of tetramethylammonium hydroxide (25 mass %, available from Tokuyama Corporation), and 1.74 g of the metal-containing solution obtained by the above operation, followed by mixing to obtain a residue removing solution having the composition described in Example 1. Examples 2 to 12 and 36 to 38 were also produced and evaluated by the similar method. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

A glass column (available from As One Corporation, Biocolumn CF-50TK) having an inner diameter of 45 mm was charged with 200 mL of a strongly acidic ion exchange resin (available from Organo Corporation, AmberLite IR-120BNa). Subsequently, 1 L of 1N hydrochloric acid (available from Wako Pure Chemical Industry, Ltd., for volumetric analysis) was passed through an ion exchange resin column to replace with a hydrogen form, and 1 L of ultrapure water was passed therethrough to rinse the ion exchange resin. Furthermore, 2 L of a 2.38% tetramethylammonium hydroxide solution was passed through the ion exchange resin exchanged to the hydrogen form, and ion exchange was implemented from the hydrogen form to the tetramethylammonium form. After the ion exchange, 1 L of ultrapure water was passed through the ion exchange resin to rinse the resin.

Commercially available sodium bromite was added to ultrapure water to obtain a sodium bromite solution. This sodium bromite solution was passed through the ion exchange resin which had been ion-exchanged to the tetramethylammonium form to obtain a tetramethylammonium bromite solution by substituting sodium ions with tetramethylammonium ions.

Ultrapure water, the tetramethylammonium bromite solution, an onium salt, tetramethylammonium hydroxide (25 mass %, available from Tokuyama Corporation), hydrochloric acid, and the metal-containing solution obtained by the operation described above were added and mixed to have the concentrations described in Tables 1 and 3, thereby obtaining residue removing solutions having the compositions described in Examples 13 to 15 and 39. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

Commercially available sodium bromate was added to ultrapure water to obtain a sodium bromate solution. This sodium bromate solution was passed through an ion exchange resin ion-exchanged to a tetramethylammonium form to obtain a tetramethylammonium bromate solution by substituting sodium ions with tetramethylammonium ions.

Ultrapure water, the tetramethylammonium bromate solution, an onium salt, tetramethylammonium hydroxide (25 mass %, available from Tokuyama Corporation), hydrochloric acid, and the metal-containing solution obtained by the operation described above were added and mixed to have the concentrations described in Table 1, thereby obtaining residue removing solutions having the compositions described in Examples 16 to 18. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

Commercially available sodium chlorite was added to ultrapure water to obtain a sodium chlorite solution. This sodium chlorite solution was passed through an ion exchange resin ion-exchanged to a tetramethylammonium form to obtain a tetramethylammonium chlorite solution by substituting sodium ions with tetramethylammonium ions.

Ultrapure water, the tetramethylammonium chlorite solution, an onium salt, tetramethylammonium hydroxide (25 mass %, available from Tokuyama Corporation), hydrochloric acid, and the metal-containing solution obtained by the operation described above were added and mixed to have the concentrations described in Table 2, thereby obtaining residue removing solutions having the compositions described in Examples 37 to 39. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

Commercially available sodium chlorate was added to ultrapure water to obtain a sodium chlorate solution. This sodium chlorate solution was passed through an ion exchange resin ion-exchanged to a tetramethylammonium form to obtain a tetramethylammonium chlorate solution by substituting sodium ions with tetramethylammonium ions.

Ultrapure water, the tetramethylammonium chlorate solution, an onium salt, tetramethylammonium hydroxide (25 mass %, available from Tokuyama Corporation), hydrochloric acid, and the metal-containing solution obtained by the operation described above were added and mixed to have the concentrations described in Tables 2 and 3, thereby obtaining residue removing solutions having the compositions described in Examples 33 to 35 and 43. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

To the tetramethylammonium hypochlorite solution obtained by the above operation, the equivalent mol of tetramethylammonium bromide was added to obtain a tetramethylammonium hypobromite solution.

To this tetramethylammonium hypobromite solution, the tetramethylammonium hypochlorite solution obtained by the above operation, a tetramethylammonium bromite solution, a tetramethylammonium chlorate solution, an onium salt, tetramethylammonium hydroxide (25 mass %, available from Tokuyama Corporation), hydrochloric acid, and the metal-containing solution obtained by the above operation were added to have the concentrations shown in Table 4 and mixed to obtain residue removing solutions having the compositions shown in Examples 44 to 46. Note that the metal contained in the residue removing solution is the metal described in Metal Contained in Dry Etching Residue Removing Solution described above, and the metal concentration in the residue removing solution is a concentration calculated from the total content of Mg, Ca, Na, and K contained in the residue removing solution.

### (Measurement of Metal Amount in Treatment Solution)

For the measurement of the metal amount, a triple quadrupole inductively coupled plasma mass spectrometer (ICP-8900, available from Agilent Technologies, Inc.) was used. A calibration curve was prepared using an element standard solution for ICP analysis containing Mg, Ca, Na, K, Fe, Cr, Ni, Zn, Cu, and Al, and the metal concentration in the treatment solution was measured.

### (Evaluation)

Using the produced residue removing solution, the dry etching residue removal rate, the amount of RuO₄ gas generated, the stability of the concentration of the oxidizing agent in the residue removing solution, and the surface smoothness after etching were evaluated by the above-described methods.

The compositions of the residue removing solutions and each evaluation result are shown in Tables 1 to 4.

### (Onium Salt)

A: benzyldimethylphenylammonium ion
B: (1-ethoxy-1-oxopropan-2-yl) triphenylphosphonium ion
C: 1,1′-(decan-1,10-diyl) bis[4-aza-1-azoniabicyclo[2.2.2]octane]diion
D: butyltriphenylphosphonium ion
E: (2-carboxyethyl) triphenylphosphonium ion
F: (3-carboxypropyl) triphenylphosphonium ion
G: (4-carboxybutyl) triphenylphosphonium ion
H: allyltriphenylphosphonium ion
I: tetraphenylphosphonium ion
J: benzyltriphenylphosphoniumn ion

TABLE 1

| | | Composition | | | | | | | Effect | | |
|---|---|---|---|---|---|---|---|---|---|---|---|
| | | | Oxidizing | | | Metal | | Onium | | | Storage stability |
| | | | agent con- | | | concen- | | salt con- | Residue | | evaluation |
| | Etching | Oxidizing | centration | | Surface | tration | Onium | centration | removal | RuO₄ | of oxidizing |
| | form | agent | [M] | pH | tension | (ppt) | salt | (ppm) | rate | gas | agent |
| Example 1 | Dry etching + | BrO⁻ | 0.0001 | 12.5 | 72.5 | 43.0 | B | 500 | C | A | A |
| | residue removing | | | | | | | | | | |
| | solution | | | | | | | | | | |
| Example 2 | Dry etching + | BrO⁻ | 0.003 | 12.5 | 72.5 | 46.4 | H | 500 | B | A | A |
| | residue removing | | | | | | | | | | |
| | solution | | | | | | | | | | |
| Example 3 | Dry etching + | BrO⁻ | 0.007 | 12.5 | 72.5 | 47.3 | D | 500 | B | A | A |
| | residue removing | | | | | | | | | | |
| | solution | | | | | | | | | | |
| Example 4 | Dry etching + | BrO⁻ | 0.05 | 10.0 | 72.5 | 45.0 | C | 500 | A | C | A |
| | residue removing | | | | | | | | | | |
| | solution | | | | | | | | | | |
| Example 5 | Dry etching + | BrO⁻ | 0.05 | 12.5 | 72.5 | 47.0 | I | 500 | A | A | A |
| | residue removing | | | | | | | | | | |
| | solution | | | | | | | | | | |
| Example 6 | Dry etching + | BrO⁻ | 0.05 | 12.5 | 72.5 | 47.6 | — | — | A | C | A |
| | residue removing | | | | | | | | | | |
| | solution | | | | | | | | | | |
| Example 7 | Dry etching + | BrO⁻ | 0.05 | 12.5 | 72.5 | 48.4 | E | 3000 | B | A | B |
| | residue removing | | | | | | | | | | |
| | solution | | | | | | | | | | |
| Example 8 | Dry etching + | BrO⁻ | 0.05 | 12.5 | 72.5 | 43.6 | C | 10000 | B | A | B |
| | residue removing | | | | | | | | | | |
| | solution | | | | | | | | | | |
| Example 9 | Dry etching + | BrO⁻ | 0.05 | 12.5 | 72.5 | 45.4 | A | 20000 | C | A | C |
| | residue removing | | | | | | | | | | |
| | solution | | | | | | | | | | |
| Example 10 | Dry etching + | BrO⁻ | 0.05 | 13.5 | 72.5 | 41.0 | J | 500 | B | B | A |
| | residue removing | | | | | | | | | | |
| | solution | | | | | | | | | | |
| Example 11 | Dry etching + | BrO⁻ | 0.16 | 12.5 | 72.5 | 46.2 | B | 500 | A | A | B |
| | residue removing | | | | | | | | | | |
| | solution | | | | | | | | | | |
| Example 12 | Dry etching + | BrO⁻ | 0.50 | 12.5 | 72.5 | 43.2 | F | 500 | A | A | C |
| | residue removing | | | | | | | | | | |
| | solution | | | | | | | | | | |
| Example 13 | Dry etching + | BrO₂⁻ | 0.20 | 12.0 | 72.5 | 44.6 | I | 500 | B | A | C |
| | residue removing | | | | | | | | | | |
| | solution | | | | | | | | | | |
| Example 14 | Dry etching + | BrO₂⁻ | 0.10 | 12.0 | 72.5 | 44.8 | A | 500 | B | A | B |
| | residue removing | | | | | | | | | | |
| | solution | | | | | | | | | | |
| Example 15 | Dry etching + | BrO₂⁻ | 0.05 | 12.0 | 72.5 | 46.3 | G | 500 | B | A | A |
| | residue removing | | | | | | | | | | |
| | solution | | | | | | | | | | |
| Example 16 | Dry etching + | BrO₃⁻ | 0.20 | 11.0 | 72.5 | 46.6 | C | 500 | C | C | C |
| | residue removing | | | | | | | | | | |
| | solution | | | | | | | | | | |
| Example 17 | Dry etching + | BrO₃⁻ | 0.10 | 11.0 | 72.5 | 47.0 | B | 500 | C | C | B |
| | residue removing | | | | | | | | | | |
| | solution | | | | | | | | | | |
| Example 18 | Dry etching + | BrO₃⁻ | 0.05 | 11.0 | 72.5 | 44.2 | F | 500 | C | C | A |
| | residue removing | | | | | | | | | | |
| | solution | | | | | | | | | | |
| Example 19 | Dry etching + | ClO⁻ | 0.0001 | 12.5 | 72.5 | 43.9 | D | 500 | C | A | A |
| | residue removing | | | | | | | | | | |
| | solution | | | | | | | | | | |
| Example 20 | Dry etching + | ClO⁻ | 0.003 | 12.5 | 72.5 | 40.3 | A | 500 | B | A | A |
| | residue removing | | | | | | | | | | |
| | solution | | | | | | | | | | |

Note)
The metal concentration is a concentration calculated from the total content of Mg, Ca, Na, and K.

TABLE 2

| | | Composition | | | | | | | Effect | | |
|---|---|---|---|---|---|---|---|---|---|---|---|
| | | | Oxidizing | | | Metal | | Onium | | | Storage stability |
| | | | agent con- | | | concen- | | salt con- | Residue | | evaluation |
| | Etching | Oxidizing | centration | | Surface | tration | Onium | centration | removal | RuO₄ | of oxidizing |
| | form | agent | [M] | pH | tension | (ppt) | salt | (ppm) | rate | gas | agent |
| Example 21 | Dry etching + | ClO⁻ | 0.014 | 12.5 | 72.5 | 45.0 | H | 500 | B | A | A |
| | residue removing | | | | | | | | | | |
| | solution | | | | | | | | | | |
| Example 22 | Dry etching + | ClO⁻ | 0.16 | 10.0 | 72.5 | 48.8 | E | 500 | A | C | A |
| | residue removing | | | | | | | | | | |
| | solution | | | | | | | | | | |
| Example 23 | Dry etching + | ClO⁻ | 0.16 | 12.5 | 72.5 | 47.2 | G | 500 | A | A | A |
| | residue removing | | | | | | | | | | |
| | solution | | | | | | | | | | |
| Example 24 | Dry etching + | ClO⁻ | 0.16 | 12.5 | 72.5 | 49.8 | — | — | A | C | A |
| | residue removing | | | | | | | | | | |
| | solution | | | | | | | | | | |
| Example 25 | Dry etching + | ClO⁻ | 0.16 | 12.5 | 72.5 | 49.1 | C | 3000 | B | A | B |
| | residue removing | | | | | | | | | | |
| | solution | | | | | | | | | | |
| Example 26 | Dry etching + | ClO⁻ | 0.16 | 12.5 | 72.5 | 40.6 | G | 10000 | B | A | B |
| | residue removing | | | | | | | | | | |
| | solution | | | | | | | | | | |
| Example 27 | Dry etching + | ClO⁻ | 0.16 | 12.5 | 72.5 | 40.7 | F | 20000 | C | A | C |
| | residue removing | | | | | | | | | | |
| | solution | | | | | | | | | | |
| Example 28 | Dry etching + | ClO⁻ | 0.16 | 13.5 | 72.5 | 49.9 | H | 500 | B | B | A |
| | residue removing | | | | | | | | | | |
| | solution | | | | | | | | | | |
| Example 29 | Dry etching + | ClO⁻ | 0.50 | 12.5 | 72.5 | 47.4 | A | 500 | A | A | C |
| | residue removing | | | | | | | | | | |
| | solution | | | | | | | | | | |
| Example 30 | Dry etching + | ClO₂⁻ | 0.20 | 13.3 | 72.5 | 42.7 | C | 500 | C | B | C |
| | residue removing | | | | | | | | | | |
| | solution | | | | | | | | | | |
| Example 31 | Dry etching + | ClO₂⁻ | 0.10 | 13.3 | 72.5 | 40.6 | C | 500 | C | B | B |
| | residue removing | | | | | | | | | | |
| | solution | | | | | | | | | | |
| Example 32 | Dry etching + | ClO₂⁻ | 0.05 | 13.3 | 72.5 | 48.9 | B | 500 | C | B | A |
| | residue removing | | | | | | | | | | |
| | solution | | | | | | | | | | |
| Example 33 | Dry etching + | ClO₃⁻ | 0.20 | 11.0 | 72.5 | 44.2 | F | 500 | B | C | C |
| | residue removing | | | | | | | | | | |
| | solution | | | | | | | | | | |
| Example 34 | Dry etching + | ClO₃⁻ | 0.10 | 11.0 | 72.5 | 46.1 | I | 500 | B | C | B |
| | residue removing | | | | | | | | | | |
| | solution | | | | | | | | | | |
| Example 35 | Dry etching + | ClO₃⁻ | 0.05 | 11.0 | 72.5 | 42.4 | F | 500 | B | C | A |
| | residue removing | | | | | | | | | | |
| | solution | | | | | | | | | | |
| Comparative | Dry etching + | Orthoperiodic | 0.01 | 1.0 | 72.5 | 46.0 | I | 500 | D | D | D |
| Example 1 | residue removing | acid | | | | | | | | | |
| | solution | | | | | | | | | | |
| Comparative | Dry etching + | BrO⁻ | 0.05 | 5.0 | 72.5 | 41.9 | E | 500 | C | D | D |
| Example 2 | residue removing | | | | | | | | | | |
| | solution | | | | | | | | | | |
| Comparative | Dry etching + | ClO⁻ | 0.16 | 5.0 | 72.5 | 49.6 | G | 500 | C | D | D |
| Example 3 | residue removing | | | | | | | | | | |
| | solution | | | | | | | | | | |
| Comparative | Dry etching + | BrO₂⁻ | 0.10 | 3.5 | 72.5 | 48.0 | I | 500 | C | D | D |
| Example 4 | residue removing | | | | | | | | | | |
| | solution | | | | | | | | | | |
| Comparative | Dry etching + | ClO₃⁻ | 0.40 | 6.0 | 72.5 | 43.1 | C | 500 | C | D | D |
| Example 5 | residue removing | | | | | | | | | | |
| | solution | | | | | | | | | | |

Note)
The metal concentration is a concentration calculated from the total content of Mg, Ca, Na, and K.

TABLE 3

| | | Composition | | | | | | | | |
|---|---|---|---|---|---|---|---|---|---|---|
| | | | Oxidizing agent | | | Metal | | Onium | Effect | |
| | | | concen- | | | concen- | | salt con- | Residue | |
| | Etching | Oxidizing | tration | | Surface | tration | Onium | centration | removal | Surface |
| | form | agent | [M] | pH | tension | (ppt) | salt | (ppm) | rate | smoothness |
| Example 36 | Dry etching + | BrO⁻ | 0.05 | 12.5 | 72.5 | 42.2 | E | 500 | A | A |
| | residue removing | | | | | | | | | |
| | solution | | | | | | | | | |
| Example 37 | Dry etching + | BrO⁻ | 0.05 | 12.5 | 72.5 | 99.4 | J | 500 | A | B |
| | residue removing | | | | | | | | | |
| | solution | | | | | | | | | |
| Example 38 | Dry etching + | BrO⁻ | 0.05 | 12.5 | 72.5 | 503.8 | A | 500 | A | C |
| | residue removing | | | | | | | | | |
| | solution | | | | | | | | | |
| Example 39 | Dry etching + | BrO₂⁻ | 0.05 | 12.0 | 72.5 | 48.5 | D | 500 | B | A |
| | residue removing | | | | | | | | | |
| | solution | | | | | | | | | |
| Example 40 | Dry etching + | ClO⁻ | 0.16 | 12.5 | 72.5 | 99.8 | F | 500 | A | B |
| | residue removing | | | | | | | | | |
| | solution | | | | | | | | | |
| Example 41 | Dry etching + | ClO⁻ | 0.16 | 12.5 | 72.5 | 360.0 | B | 500 | A | C |
| | residue removing | | | | | | | | | |
| | solution | | | | | | | | | |
| Example 42 | Dry etching + | ClO⁻ | 0.16 | 12.5 | 72.5 | 2.63 | C | 500 | A | A |
| | residue removing | | | | | | | | | |
| | solution | | | | | | | | | |
| Example 43 | Dry etching + | ClO₃⁻ | 0.05 | 11.0 | 72.5 | 44.9 | G | 500 | B | A |
| | residue removing | | | | | | | | | |
| | solution | | | | | | | | | |
| Comparative | Only dry etching | — | — | — | — | — | — | — | D | C |
| Example 6 | | | | | | | | | | |
| Comparative | Only wet etching | BrO⁻ | 0.05 | 12.5 | 72.5 | 40.2 | D | 500 | C | D |
| Example 7 | | | | | | | | | | |
| Comparative | Dry etching + | BrO⁻ | 0.05 | 12.5 | 72.5 | 1104.5 | I | 500 | A | D |
| Example 8 | residue removing | | | | | | | | | |
| | solution | | | | | | | | | |
| Comparative | Dry etching + | ClO⁻ | 0.16 | 12.5 | 72.5 | 1056.6 | H | 500 | A | D |
| Example 9 | residue removing | | | | | | | | | |
| | solution | | | | | | | | | |
| Comparative | Dry etching + | BrO₂⁻ | 0.10 | 12.0 | 72.5 | 1502.8 | A | 500 | A | D |
| Example 10 | residue removing | | | | | | | | | |
| | solution | | | | | | | | | |
| Comparative | Dry etching + | ClO₃⁻ | 0.40 | 11.0 | 72.5 | 1303.4 | D | 500 | A | D |
| Example 11 | residue removing | | | | | | | | | |
| | solution | | | | | | | | | |
| Comparative | Dry etching + | BrO⁻ | 0.05 | 12.5 | 72.5 | Less than 0.01 | A | 500 | A | D |
| Example 12 | residue removing | | | | | | | | | |
| | solution | | | | | | | | | |

Note)
The metal concentration is a concentration calculated from the total content of Mg, Ca, Na, and K.

TABLE 4

| | | Composition | | | | | | | | | Effect |
|---|---|---|---|---|---|---|---|---|---|---|---|
| | | | Oxidizing 1 | | Oxidizing | | | | | Onium | Storage |
| | | | agent | | agent 2 | | | Metal | | salt | stability |
| | | | concen- | | concen- | | | concen- | | concen- | evaluation |
| | Etching | Oxidizing | tration | Oxidizing | tration | | Surface | tration | Onium | tration | of oxidizing |
| | form | agent 1 | [M] | agent 2 | [M] | pH | tension | (ppt) | salt | (ppm) | agent |
| Example 44 | Dry etching + | BrO⁻ | 0.16 | ClO⁻ | 0.08 | 12.5 | 72.5 | 44.6 | B | 500 | A |
| | residue removing | | | | | | | | | | |
| | solution | | | | | | | | | | |
| Example 45 | Dry etching + | BrO⁻ | 0.16 | BrO₂⁻ | 0.08 | 12.5 | 72.5 | 42.2 | I | 500 | A |
| | residue removing | | | | | | | | | | |
| | solution | | | | | | | | | | |
| Example 46 | Dry etching + | BrO⁻ | 0.16 | ClO₃⁻ | 0.08 | 12.5 | 72.5 | 41.3 | F | 500 | A |
| | residue removing | | | | | | | | | | |
| | solution | | | | | | | | | | |

Note)
The metal concentration is a concentration calculated from the total content of Mg, Ca, Na, and K.

1. A dry etching residue removing solution for removing a residue after dry etching, the dry etching residue removing solution comprising:
one or more oxidizing agents selected from the group consisting of a hypobromite ion, a bromate ion, a bromite ion, a hypochlorite ion, a chlorate ion, and a chlorite ion; one or more metals selected from the group consisting of Mg, Ca, Na, and K; and water, wherein
the residue removing solution has a pH of 9.5 or higher and 14 or lower at 25° C., and a total content of Mg, Ca, Na, and K in the dry etching residue removing solution is 0.01 ppt or more and 1000 ppt or less.

2. The dry etching residue removing solution according to claim 1, wherein a concentration of the oxidizing agent is 0.0001 mol/L or more and 0.40 mol/L or less.

3. The dry etching residue removing solution according to claim 1, wherein the oxidizing agent is a hypochlorite ion, and a concentration of the hypochlorite ion is 0.001 mol/L or more and 0.40 mol/L or less.

4. The dry etching residue removing solution according to claim 2, wherein the oxidizing agent is a hypobromite ion, and a concentration of the hypobromite ion is 0.001 mol/L or more and 0.20 mol/L or less.

5. The dry etching residue removing solution according to claim 1, further comprising an onium ion, wherein the residue removing solution has a surface tension of 60 mN/m or more and 75 mN/m or less.

6. The dry etching residue removing solution according to claim 5, wherein the onium ion is one or more selected from the group consisting of onium ions represented by Formula (1) to Formula (6): 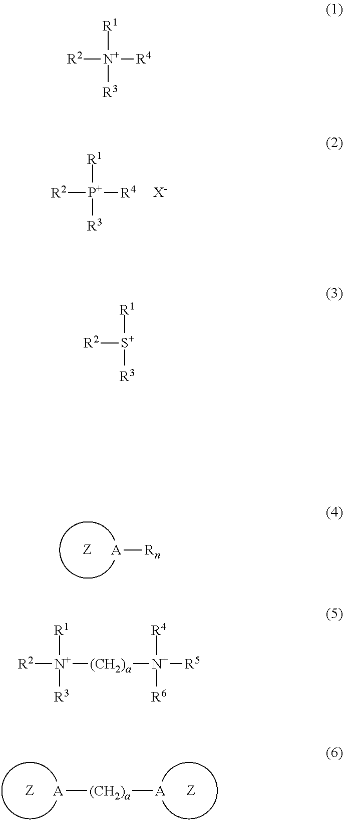
(in Formula (1) to Formula (6),
R¹, R², R³, R⁴, R⁵, and R⁶ are each independently an alkyl group having a carbon number from 2 to 9, an allyl group, an aralkyl group having an alkyl group having a carbon number from 1 to 9, or an aryl group, at least one hydrogen in an aryl group and a ring of an aryl group in the aralkyl group is optionally substituted with fluorine, chlorine, an alkyl group having a carbon number from 1 to 9, an alkenyl group having a carbon number from 2 to 9, an alkoxy group having a carbon number from 1 to 9, or an alkenyloxy group having a carbon number from 2 to 9, and at least one hydrogen in these groups is optionally substituted with fluorine, chlorine, bromine, or iodine,
A is an ammonium ion or a phosphonium ion,
Z is an aromatic group or alicyclic group which optionally contains a nitrogen, sulfur, or oxygen atom, and in the aromatic group or the alicyclic group, carbon or nitrogen optionally has chlorine, bromine, fluorine, iodine, at least one alkyl group having a carbon number from 1 to 9, at least one alkenyloxy group having a carbon number from 2 to 9, an aromatic group which is optionally substituted with at least one alkyl group having a carbon number from 1 to 9, or an alicyclic group which is optionally substituted with at least one alkyl group having a carbon number from 1 to 9,
R is chlorine, bromine, fluorine, iodine, an alkyl group having a carbon number from 1 to 9, an allyl group, an aromatic group which is optionally substituted with at least one alkyl group having a carbon number from 1 to 9, or an alicyclic group which is optionally substituted with at least one alkyl group having a carbon number from 1 to 9, n is an integer of 1 or 2 and represents the number of R, when n is 2, Rs are optionally the same or different and optionally form a ring, and
a is an integer of 1 to 10).

7. The dry etching residue removing solution according to claim 5, wherein a concentration of the onium ion is 1 mass ppm or more and 10000 mass ppm or less.

8. A method for removing a dry etching residue of a semiconductor wafer, the method comprising a step of bringing the dry etching residue removing solution according to claim 1 into contact with a semiconductor wafer.

9. A method for producing a semiconductor device, the method comprising a step of dry-etching a semiconductor wafer; and a step of removing a dry etching residue with the dry etching residue removing solution according to claim 1.

10. The method for producing a semiconductor device according to claim 9, wherein the semiconductor wafer is a semiconductor wafer containing a ruthenium-based metal.
